(19) United States
(12) Patent Application Publication
(10) Pub. No.: US 2025/0324611 A1
(43) Pub. Date: Oct. 16, 2025

(54) SEMICONDUCTOR DEVICE

(71) Applicant: Renesas Electronics Corporation, Tokyo (JP)

(72) Inventors: Ken MATSUBARA, Tokyo (JP); Mitsuhiro HOTTA, Tokyo (JP); Koichi TAKEDA, Tokyo (JP); Kiyotada FUNANE, Tokyo (JP); Takahiro SHIMOI, Tokyo (JP)

(21) Appl. No.: 19/066,325

(22) Filed: Feb. 28, 2025

Related U.S. Application Data
(60) Provisional application No. 63/634,846, filed on Apr. 16, 2024.

(30) Foreign Application Priority Data
Jun. 6, 2024 (JP) 2024-092451

(51) Int. Cl. H10B 61/00

(52) U.S. Cl. CPC H10B 61/10

(57) ABSTRACT

A semiconductor device includes a memory array. In a plan view, the memory array has a memory cell region arranged at a center portion and dummy cell regions arranged at an outer circumferential portion. In the dummy cell regions, a dummy cell connected to a word line is arranged, the dummy cell has a transistor whose gate terminal is connected to the word line and to whose drain terminal a ground voltage is supplied. At a time of performing a reading operation of the memory cell, the transistor is made in a conductive state so that the ground voltage is supplied to the source lines.

### CROSS-REFERENCE TO RELATED APPLICATIONS

The present application claims priorities from U.S. Patent Application No. 63/634,846 filed on Apr. 16, 2024 and Japanese Patent Application No. filed on 2024-92451 filed on Jun. 6, 2024, the contents of which are hereby incorporated by reference to this application.

### BACKGROUND

The present invention relates to a semiconductor device, for example, a semiconductor device having a memory array in which a plurality of resistance-change memory cells are arranged in a matrix.

The resistance-change memory cell (hereinafter, simply called a memory cell) means a memory cell having a storage element whose resistance value changes depending on memorizing information. As an electrically rewritable non-volatile storage device (hereinafter, also called a non-volatile storage device) configured by such a memory cell, for example, there is a Magnetoresistive Random Access Memory (hereinafter, also called a MRAM).

The plurality of memory cells are arranged in the matrix, configure the memory array, and are formed into the non-volatile storge device. For example, in reading data from the memory cell, the memory cell is specified from the memory array by an address signal, and the data is read by the specified memory cell. In this case, a characteristic change due to manufacturing variation of the memory cell arranged at an outer circumferential portion in the memory array is remarkably difficult in comparison with a characteristic change due to manufacturing variation of the memory cell arranged at a center portion in the memory array. For example, a resistance value of the memory cell arranged at the outer circumferential portion varies comparatively greatly depending the manufacturing variation, which makes it difficult to read the correct information.

There is disclosed a technique listed below. [Non-Patent Document 1] “A 16 nm 32 Mb Emmbedded STT-MARN with a 6 ns Read-Access Time, a 1M-Cycle With Endurance, 20-Year Retention at 150° C. and MT JOOTP Solutions for Magnetic Immunity”, ISSCC 2023/SESSION 33/NON-VOLATILE MEMORY AND COMPUTE-IN-MEMORY/33.1, 2023 IEEE International Solid-State Circuit Conference

To warrant the reading of the correct information, a dummy cell region in which the memory cell (not disclosed by a user) not specified by the address signal is formed is arranged at the outer circumferential portion in the memory array. For example, Non-Patent Document 1 discloses that a dummy cell region is arranged at an outer circumferential portion in a memory array and the memory cell arranged in the dummy cell region is used as a One Time Programmable Memory (hereinafter, also called an OTP).

### SUMMARY

Generally, as a size of the memory cell is shrunk for advancing miniaturization, the characteristic change due to the manufacturing variation of the memory cell arranged at the outer circumferential portion in the memory array becomes large, so that it is required to increase the number of memory cells arranged in the dummy cell region. Particularly, in a case of the MRAM, if a difference of the resistance value of the memory cell (a difference between a high resistance value and a low resistance value corresponding to the memorized data) is small and the manufacturing variation of the memory cell arranged at the outer circumferential portion in the memory array is large, there is a high possibility that reading errors occur, so that the increase in the number of memory cells arranged in the memory cell region becomes further necessary.

As shown in Non-Patent Document 1, if the memory cell arranged in the dummy cell region is used as an OPT which stores trimming information, a part of the dummy cell region may effectively be used. However, since the trimming information and the like do not require so large capacity, the memory cell arranged in the dummy cell region becomes largely unused. In addition, the memory cell configured by one storage element like the MRAM and one selection transistor is arranged in the dummy cell region together with the memory cell configured only by a selection transistor having no storage element. Since having no storage element, such a memory cell cannot be used as the OTP and becomes an unused memory cell. Therefore, the number of unused memory cells among the memory cells arranged in the dummy cell region further increases.

Even if the size of the memory cell is shrunk, the increase in the number of memory cells arranged in the dummy cell region becomes necessary. Consequently, the dummy cell region increases, an area ratio of the dummy cell region in the memory array becomes higher than that before the shrinking, and the size of the effective memory cell becomes larger. Therefore, the present inventors have considered miniaturization of a semiconductor device having the memory array by effectively applying the dummy cell region.

An outline of a representative one out of embodiments disclosed in the present application will briefly be explained as follows.

That is, a semiconductor device according to one embodiment includes a memory array that has a pair of first sides extending in a first direction and a pair of second sides extending in a second direction intersecting with the first sides and that has a plurality of rows parallel to the first sides and a plurality of columns parallel to the second sides.

Here, in a plan view, the memory array has a memory cell region arranged between the pair of first sides, and a dummy cell region arranged between the memory cell region and the first sides. In the memory array, a first word line and a plurality of memory cells having a first storage element and a first transistor, whose gate terminal is connected to the first word line, are arranged on each row arranged in the memory cell region; and a second word line and a plurality of first dummy cells having a second transistor, whose gate terminal is connected to the word line and to whose drain terminal a predetermined voltage is supplied, are arranged on each row arranged in the dummy cell region. In addition, in the memory array, a source line and a bit line are arranged on each column; a source terminal of the first transistor of the memory cell is connected to the source line arranged on each column arranged in the memory cell region, and a drain terminal of the first transistor of the memory cell is connected via the first storage element to the bit line arranged on each column arranged in the memory cell region; and a source terminal of the second transistor of the first dummy cell is connected to the source line arranged on each column arranged in the dummy cell region.

The plurality of memory cells are arranged at a first pitch in the first direction and at a second pitch in the second direction in the memory cell region, and the plurality of first dummy cells arranged at the first pitch in the first direction and at the second pitch in the second direction in the dummy cell region.

Further, the semiconductor device has a row decoder connected to the first word line and selecting the first word line according to a row address signal at a time of performing a reading operation, and a control circuit connected to the second word line and supplying a selection signal for making the second transistor of the first dummy cell in a conductive state so that the predetermined voltage is supplied to the source line at the time of performing the reading operation.

The other problems and novel features will be apparent from the present specification and the accompanying drawings.

According to one embodiment, a semiconductor device that is capable of achieving miniaturization and has a memory array can be provided.

### BRIEF DESCRIPTION OF THE DRAWINGS

FIG. 1 is a block diagram showing a configuration of a non-volatile storage device built in a semiconductor device according to a first embodiment.

FIG. 2A is a circuit diagram showing a dummy cell and a dummy cell according to the first embodiment.

FIG. 2B is a circuit diagram showing the dummy cell and the dummy cell according to the first embodiment.

FIG. 3 is a planar diagram showing a configuration of the memory cell according to the first embodiment.

FIG. 4 is a cross-sectional view showing the configuration of the memory cell according to the first embodiment.

FIG. 5 is a circuit diagram showing a configuration of a memory array according to the first embodiment.

FIG. 6 is a block diagram showing a configuration of the semiconductor device according to the first embodiment.

### DETAILED DESCRIPTION

Hereinafter, each embodiment of the present invention will be explained with reference with the drawing. Note that the disclosure is merely one example, and an invention(s) that can easily be arrived at about appropriate modification with maintaining the gist of the invention by the those skilled in the art is of course included within a 30 range of the present invention.

In addition, in the present specification and each figure, the same reference numerals are denoted to components similarly to those described in previously shown figures, and a detailed description will be omitted appropriately.

### First Embodiment

### <Configuration of Semiconductor Device>

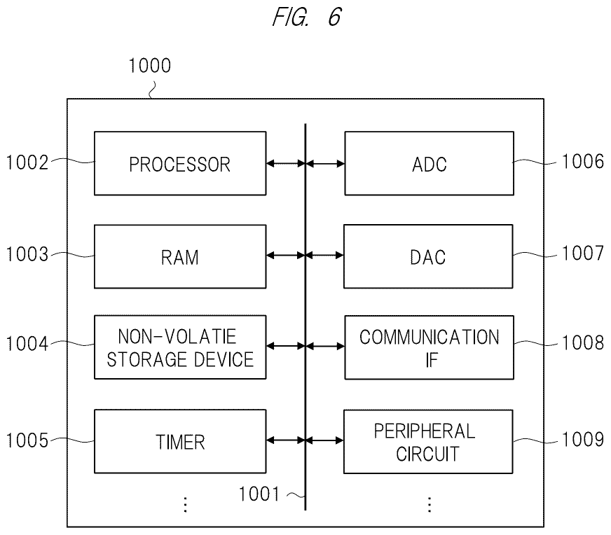

FIG. 6 is a block diagram showing a configuration of a semiconductor device according to a first embodiment. In FIG. 6, the reference numeral 1000 shows a semiconductor device. The semiconductor device 1000 includes an internal bus 1001, and a plurality of circuit blocks connected to the internal bus 1001. The internal bus 1001 and the plurality of circuit blocks that the semiconductor device includes are formed on the same semiconductor substrate.

In FIG. 6, as one example of the plurality of circuit blocks, a processor 1002, a volatile storage device (RAM) 1003, a non-volatile storage device 1004, a timer 1005, an analog/digital conversion circuit (ADC) 1006, a digital/analog conversion circuit (DAC) 10007, a communication interface circuit (communication IF) 1008, and a peripheral circuit 1009 are shown. Of course, the circuit block shown by FIG. 6 is one example, and is not limited to this.

For example, by the processor 1002 operating according to a program, a predetermined function(s) is realized through the semiconductor device 1000. To realize the predetermined function, the circuit block (for example, the non-volatile storage device 1004 and the peripheral circuit 1009, etc.) connected to the internal bus 1001 is accessed via the internal bus 1001 by the processor 1002. By this access, the processor 1002 performs, for example, a reading operation of data stored in the non-volatile storage device 1004. In this reading operation, the processor 1002 supplies an address signal (a row address signal and a column address signal) and a control signal relative to reading/writing (hereinafter, also called read/write control signal R/W) to the non-volatile storage device 1004 via the internal bus 1001. When the reading operation is instructed by the read/write control signal R/W, the non-volatile storage device 1004 outputs, to the processor 1002 via the internal bus 1001, the data of the memory cell specified (selected) according to the supplied address signal.

In the first embodiment, it will be explained as one example in which the non-volatile storage device 1004 is a MRAM and has a memory array arranging the memory cells of the MRAM in a matrix. However, the non-volatile storage device 1004 is not limited to this, and may be a storage device having a memory array in which resistance-change memory cells are arranged in a matrix.

### <Configuration of Non-Volatile Storage Device>

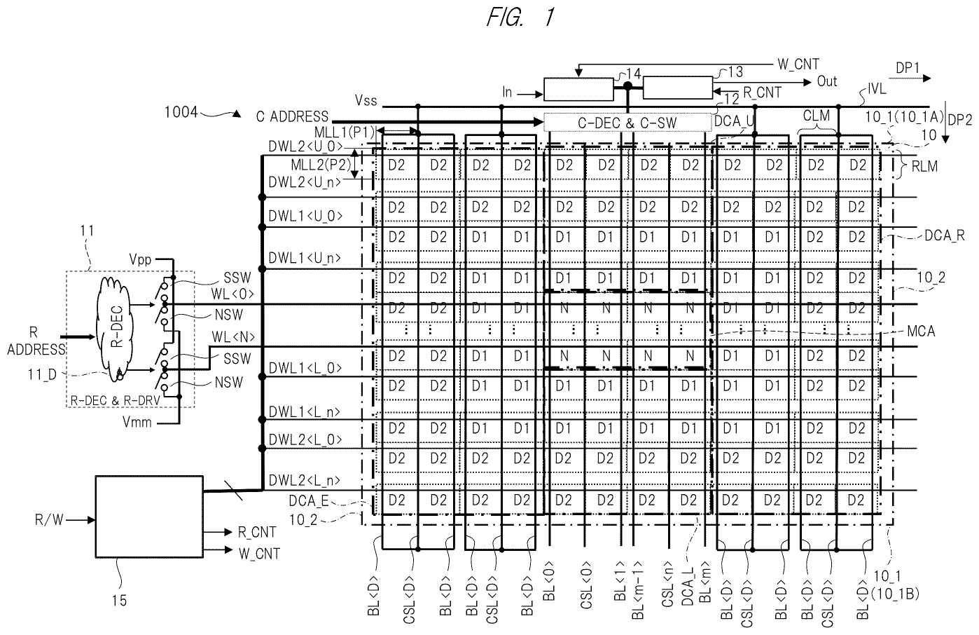

FIG. 1 is a block diagram showing a configuration of a non-volatile storage device built in a semiconductor device according to the first embodiment.

The non-volatile storage device 1004 according to the first embodiment includes a memory array 10, a row decoder (R-DEC & R-DRV) 11, a column decoder (C-DEC & C-SW) 12, a sense amplifier 13, a writing circuit 14, and a control circuit 15.

In a plan view, the row decoder 11, the column decoder 12, the sense amplifier 13, the writing circuit 14, and the control circuit 15 are arranged outside the memory array 10 on a semiconductor substrate. An inside of the memory array 10 is illustrated schematically but according to actual arrangement on the semiconductor substrate.

In the plan view, the memory array 10 has a square shape configured by a pair of first sides 10_1 extending in a first direction DP1, and a pair of second sides 10_2 extending in a second direction DP2 intersecting with (orthogonal to) the first direction DP1. A matrix configured by a plurality of rows parallel to the first sides 10_1 and a plurality of columns parallel to the second sides 10_2 is arranged on the memory array 10. In FIG. 1, one column is exemplified as the reference numeral CLM, and one row is exemplified as the reference numeral RLM.

In the memory array 10, a memory cell region MCA is arranged at a center portion of the memory array 10, and dummy cell regions DCA_U, DCA_L, DCA_R, DCA_E are arranged so as to surround the memory cell region MCA. In other words, the memory cell region MCA is arranged between one pair of first sides 10_1, a first dummy cell region DCA_U is arranged between the memory cell region MCA and one first side 10_1A out of the pair of first sides 10_1, and a second dummy cell region DCA_L is arranged between the memory cell region MCA and the other first side 10_1B out of the pair of first sides 10_1. In addition, the dummy cell regions DCA_R, DCA_E are arranged between one pair of second sides 10_2 and the memory cell region MCA.

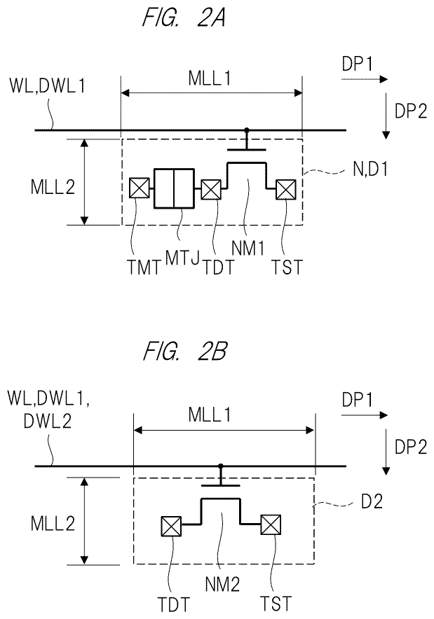

In the matrix arranged on the memory array 10, the matrix in which the memory cell region MCA (the memory cell region MCA is assigned) arranges, as shown in FIG. 1, a plurality of memory cells N. Similarly, in the matrix arranged on the memory array 10, the matrix in which the dummy cell regions DCA_U, DCA_L, DCA_R, DCA_E are arranged (the dummy cell regions are assigned) arranges, as shown in FIG. 1, a plurality of dummy cells D1, D2. Since each example of configurations of the memory cell N and the dummy cells D1, D2 is explained later by using FIG. 2, its explanation will be omitted here.

In each plan view of the memory cell and the dummy cell, respective lengths of the memory cell N and the dummy cell D1, D2 in the first direction DP1 and in the second direction DP2 are equal to one another. That is, the lengths of the memory cell N and the dummy cells D1, D2 in the first direction DP1 are the same length MLL1, and those in the second direction DP2 are the same length MLL2. The memory cell N and the dummy cells D1, D2 are arranged on the matrix of the memory array 10 without any gaps, so that the plurality of memory cells N are arranged at an interval of a pitch P1 corresponding to the length MLL1 in the first direction DP1 and at an interval of a pitch P2 corresponding to the length MLL2 in the second direction DP2. Similarly, the plurality of dummy cells D1, D2 are also arranged at the interval of the pitch P1 corresponding to the length MLL1 in the first direction DP1 and at the interval of the pitch P2 corresponding to the length MLL2 in the second direction DP2.

In each column of the matrix configuring the memory array 10, a source line and a bit line are arranged. In FIG. 1, the sources lines arranged on the columns of the memory cell region MCA and the dummy cell regions DCA_U, DCA_L are denoted by the reference numerals CSL<0> to CSL<n>, and the bit lines are denoted by the reference numerals BL<0> to BL<m>. In addition, the source lines arranged on the columns of the dummy cell regions DCA_R, DCA_E are denoted by the reference numeral CSL<D>, and the bit lines are denoted by the reference numeral BL<D>.

FIG. 1, an example in which one source line (for example, CSL<0>) is arranged with respect to two columns adjacent to each other is illustrated, but the present embodiment is not limited to this. For example, one source line and one bit line may be arranged with respect to each column. However, as shown in FIG. 1, it is possible to achieve miniaturization by sharing the source line between the columns adjacent to each other or to make wiring resistance small by thickening a wiring of the source line. A word line is arranged on each row of the matrix configuring the memory array 10. In FIG. 1, the word lines arranged on the row of the memory cell region MCA and the row of a part of the dummy cell regions DCA_R, DCA_E are denoted by the reference numerals WL<0> to WL<N>, and the word lines arranged on the row of a part of the dummy cell regions DCA_R, DCA_E and the row of the dummy cell regions DCA_U, DCA_L are denoted by the reference numerals DWL2<_0> to DWL2<U_n>, DWL1<U_0> to DWL1<U_n>, DWL2<L_0> to DWL2<L_n>, DWL1<L_0> to DWL1<L_n>.

### <<Memory Cell N and Dummy Cells D1, D2>>

Here, the memory cell N and the dummy cells D1, D2 will be explained by using the drawings. FIG. 2 is a circuit diagram showing configurations of a memory cell and a dummy cell according to the first embodiment. In the first embodiment, the configuration of the dummy cell D1 is the same as that of the memory cell N. FIG. 2A shows the configurations of the memory cell N and the dummy cell D1, and FIG. 2B shows the configuration of the dummy cell D2.

As shown in FIG. 2A, the memory cell N and the dummy cell D1 include an N channel type field effect transistor (hereinafter, simply called transistor, too) NM1 and a storage element MTJ. A gate terminal of the transistor NM1 is connected to the word line WL or DWL1, and a drain terminal TDT is connected to a terminal TMT via the storage element MTJ. In FIG. 2A, the reference numeral TST shows a source terminal of the transistor NM1. In the first embodiment, the storage element MTJ is a three-layer structure element having a magnetic tunneling junction. This three-layer structure element is an element having a structure in which a pinned layer, a tunneling layer, and a free layer are laminated, and its resistance value varies according to written data.

As shown in FIG. 2B, the dummy cell D2 has a transistor NM2. A gate terminal of the transistor NM2 is connected to the word line WL, DWL1 or DWL2. In FIG. 2B, the reference numeral TDT shows a drain terminal of the transistor NM2, and the reference numeral TST shows a source terminal of the transistor NM2.

Note that in FIG. 2, the reference numerals MLL1, MLL2 schematically show lengths of the memory cell N and the dummy cells D1, D2 in the first direction DP1 and the second direction DP2.

By returning FIG. 1, the explanation about the non-volatile storage device 1004 will be continued.

The word lines WL<0> to WL<N> are connected to the row decoder 11. The row decoder 11 has a decoder circuit 11_D and a word line driver. The decoder circuit 11_D decodes a row address signal (R address) from the processor 1002 (FIG. 6), and generates a selection signal according to the row address signal. The word line driver has a plurality of switches SSW, NSW corresponding to the word lines WL<0> to WL<N>. According to the selection signal generated by the decoder circuit 11_D, the switch SSW or NSW becomes a conductive state. When the switch SSW or NSW becomes the conductive state by the selection signal, a selection word-line voltage (power supply voltage) Vpp is supplied to the corresponding word line via this switch SSW. In contrast, when the switch NSW becomes the conductive state by the selection signal, a non-selection word-line voltage Vmm (a voltage lower than Vpp, for example, a negative voltage, ground voltage Vss, etc.) is supplied to the corresponding word line via the switch NSW.

As described in FIG. 2A, in the memory cells N arranged on the matrix of the memory cell region MCA, the gate terminal of the transistor NM1 is connected to the word line WL (WL<0> to WL<N>). In addition, the source terminal TST of the transistor NM1 in the memory cell N is connected to the source lines CSL<0> to CSL<n>, and the drain terminal of the transistor NM1 is connected to the bit lines BL<0> to BL<m> via the storage element MTJ and the terminal TMT.

The bit lines BL<0> to BL<m> is connected to the column decoder 12. In the column decoder 12, a column address signal (C address) is supplied from the processor 1002 (FIG. 6). The collum decoder 12 has a decoder circuit (C-DEC) and a column switch (C-SW) although not shown. The decoder circuit (C-DEC) decodes the column address signal, and generates the selection signal. The column switch (C-SW) selects the bit line designated by the selection signal from the bit lines BL<0> to BL<m>, and connects it to the sense amplifier 13 and the writing circuit 14.

For example, when the row address signal indicates the word line WL<0> and the column address signal indicates the bit line BL<0>, by the selection signal generated by the decoder circuit 11_D the switch SSW corresponding to the word line WL<0> becomes the conductive state, the transistors NM1 in the plurality of memory cells N connected to the word line WL<0> become the conductive state, and the storage elements MTJ in the plurality of memory cells N are connected between the corresponding bit line and source line via the transistor NM1. At this time, the decoder circuit (C-DEC) generates the selection signal for selecting the bit line BL<0> according to the column address signal, and the column switch (C-SW) connects the bit line BL<0> to the sense amplifier 13 and the writing circuit 14. Note that at this time, since the corresponding switch NSW becomes the conductive state, the transistors NM1 in the plurality of memory cells N connected to the other word line (for example, WL<N>) become the non-conduction state. As a result, the storage elements MTJ in the plurality of memory cells N connected to the other word line are electrically disconnected from the corresponding bit line.

The sense amplifier 13 is controlled by a reading control signal R_CNT, and the writing circuit 14 is controlled by a writing control signal W CNT. That is, when the reading operation is instructed by the reading control signal R_CNT, the sense amplifier 13 amplifies a voltage (a voltage following the data of the memory cell N) of the connected bit line and supplies, as reading data Out, it to the processor 1002. In contrast, when the writing operation is instructed by the writing control signal W CNT, the writing circuit 14 supplies, to the connected bit line, input data In supplied from the processor 1002, thereby performing the writing to the memory cell N.

The control circuit 15 outputs the reading control signal R_CNT indicating the reading operation and the writing signal W CNT indicating the writing operation control according to the read/write control signal R/W from the processor 1002.

In addition, the control circuit 15 is connected to the word lines DWL2<U_0> to DWL2<U_n>, DWL1<U_0> to DWL1<U_n>, DWL2<L_0> to DWL2<L_n>, DWL1<L_1> to DWL1<L_n> arranged on the rows of the dummy cell regions DCA_U, DCA_L and the rows of the parts of the dummy cell regions DCA_R, DCA_E. To the control circuit 15 according to the first embodiment, the address signal (row address signal: R address and column address signal: (address) is not supplied, and the previously determined selection signal and non-selection signal are supplied to the connected word line.

The bit line BL<D> and the source line CSL<D> arranged on the respective columns of the dummy cell regions DCA_R, DCA_E are not limited particularly, but are connected to a common wiring IVL in the first embodiment as shown in FIG. 1. The bit line BL<D> and the source line CSL<D> are not used for the reading operation and the writing operation, so that the ground voltage Vss is supplied to the wiring IVL in FIG. 1. The voltage supplied by the wiring IVL is not limited to the ground voltage Vss, but may be a voltage for prohibiting the writing or a breakdown-voltage relaxation voltage at a time of the writing. Or, the wiring IVL may be in a floating state.

In the non-volatile storage device 1004 shown in FIG. 1, the memory cell region MCA configured by the memory cells specified by the address signal (R address and C address) is arranged at a center portion in the memory array 10, and the dummy cell regions DCA_U, DCA_L, DCA_R, DCA_E configured by the dummy cell, which is not specified by the above address signal and is not opened by the user, are arranged at the outer circumferential portion in the memory array 1 surrounding the memory cell region MCA. Consequently, characteristics of the memory cell region are warranted by the dummy cell region.

As shown in FIG. 1, in the dummy cell regions DCA_U, DCA_L, DCA_R, DCA_E, the dummy cell D1 having the same configuration as that of the memory cell N is arranged in a portion (region) close to the memory cell region MCA, and the dummy cell D2 having only the transistor NM2 is arranged in its outside portion (region). Consequently, the characteristics of the storage element and the transistor configurating the memory cell N are warranted by the storage element and the transistor of the dummy cell D1 having the same configuration as that of the memory cell N, and the characteristics of the memory cell N and the transistor NM 1 of the dummy cell D1 are further warranted by the transistor NM2 of the dummy cell D2.

### <<Structure of Memory Cell>>

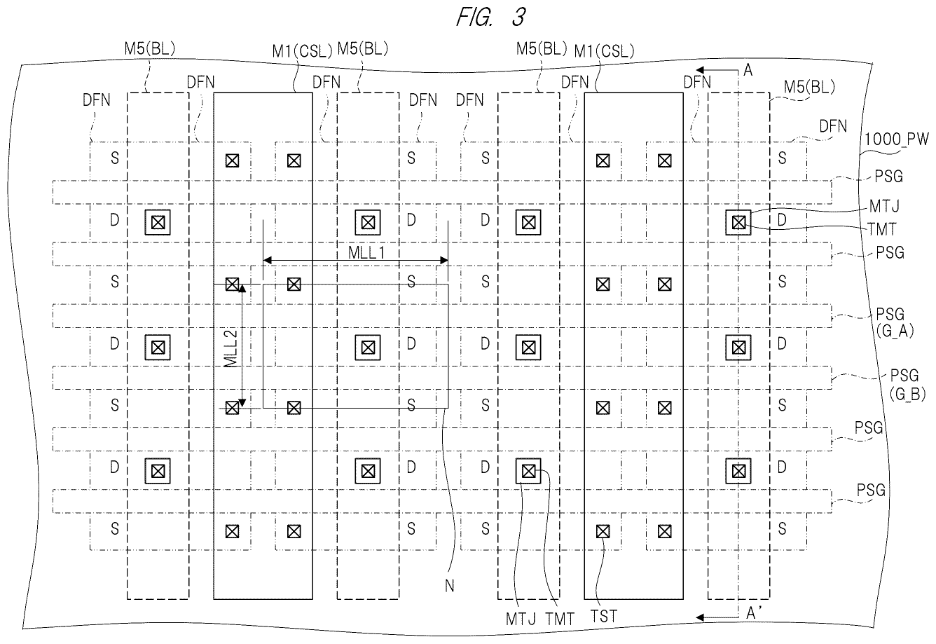

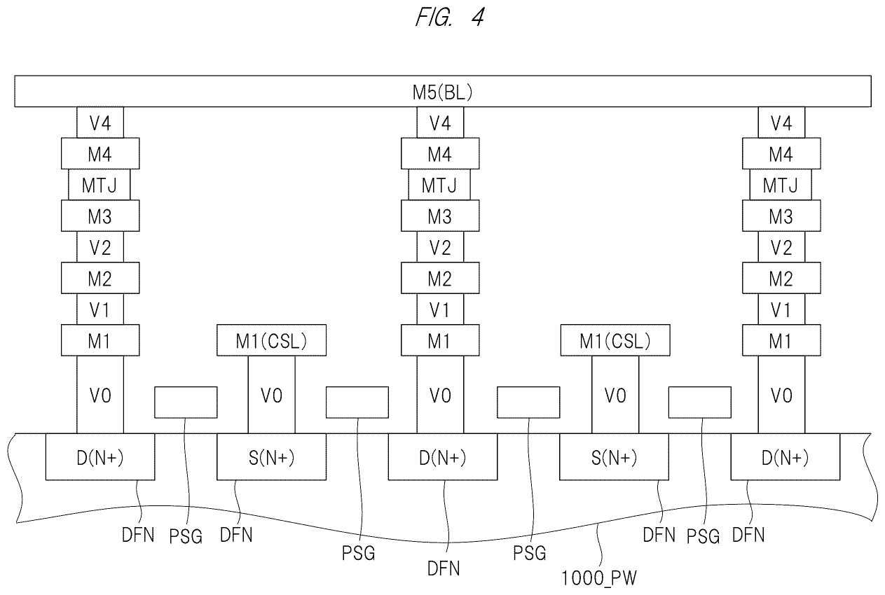

Next, a structure example of the memory cell will be explained by using the drawings. FIG. 3 is a planar view showing a structure of the memory cell according to the first embodiment. In addition, FIG. 4 is a cross-sectional view showing the structure of the memory cell according to the first embodiment. FIG. 4 shows a section taken along broken line A-A′ in FIG. 3. Hereinafter, the structure example of the memory cell will be explained by mainly using FIGS. 3 and 4.

A P-type well region 1000_PW is formed on the semiconductor substrate, and the memory cell N is formed in this P-type well region 1000_PW.

An N⁺-type diffusion layer DEN formed in the P-type well region 1000_PW configures a source region(S) and a drain region (D) of the transistor NM1 (see FIG. 2A) of the memory cell N. A gate electrode of the transistor NM1 is configured via a not-shown gate insulating film by a polysilicon layer PSG formed on the P-type well region 1000_PW between the N⁺-type diffusion layers DEN configuring the source region(S) and the drain region (D). In addition, this polysilicon layer PSG extends as the word line WL in the first direction DP1 (see FIG. 1 and FIG. 2A).

The source region(S) and the drain region (D) configured by the N⁺-type diffusion layer DEN are connected to a first-layer metal layer M1 via metal V0 filled with a via-hole provided in a not-shown interlayer insulating film. Here, the first-layer metal layer M1 connected to the source region(S) configures the source line M1 (CSL: for example, CSL<0> etc. of FIG. 1).

On a first metal layer M1, a second metal layer M2 is connected to the first metal layer M1 via metal V1 filled with a via-hole provided in the not-shown interlayer insulating film. Further, on the second metal layer M2, a third metal layer M3 is connected to the second metal layer M2 via metal V3 filled with a via-hole provided in the not-shown interlayer insulating film. The storage element MTJ is connected between the third metal layer M3 and a fourth metal layer, and a fifth metal layer M5 is connected to the fourth metal layer M4 via metal V4 filled with a via-hole provided in the not-shown interlayer insulating film. This fifth metal layer M5 configures a bit line M5 (BL: for example, BL<0> etc. of FIG. 1). Consequently, in the memory cell N, the storage element MTJ is connected between the drain terminal of the transistor NM1 and the bin line BL. Note that the source line M1 (CSL) and the bit line M5 (BL) extend in the second direction DP 2 (see FIG. 1 and FIG. 2A) intersecting with (orthogonal to) the first direction DP1.

In the plan view, one memory cell N is formed in a region surrounded by a thin broken line(s) in FIG. 3, and its length in the first direction DP1 is MLL1 and its length in the second direction DP2 is MLL2. In addition, in the structure of the memory cell N shown in FIG. 3, one word line WL is configured by two polysilicon layers PSG(G_A), PSG(G_B) arranged so as to sandwich the drain region (D) and the storage element MTJ.

The dummy cell D1 has the same configuration as that of memory cell N, so that FIGS. 3 and 4 can be considered so as to indicate the structure of the dummy cell D1. In addition, the dummy cell D2 has a structure excluding the storage element MTJ from FIGS. 3 and 4. In the plan view, the length and area of the memory cell N and the lengths (MLL1, MML2) and areas of the dummy cells D1, D2 are equal to one another.

Of course, the structure of the memory cell shown in FIGS. 3 and 4 is one example, and the present embodiment is not limited to this. For example, as explained in FIG. 1, the source line M1 (CSL) is shared by two columns, but may not be shared or may be shared by four or more columns.

### <Configuration of Memory Array>

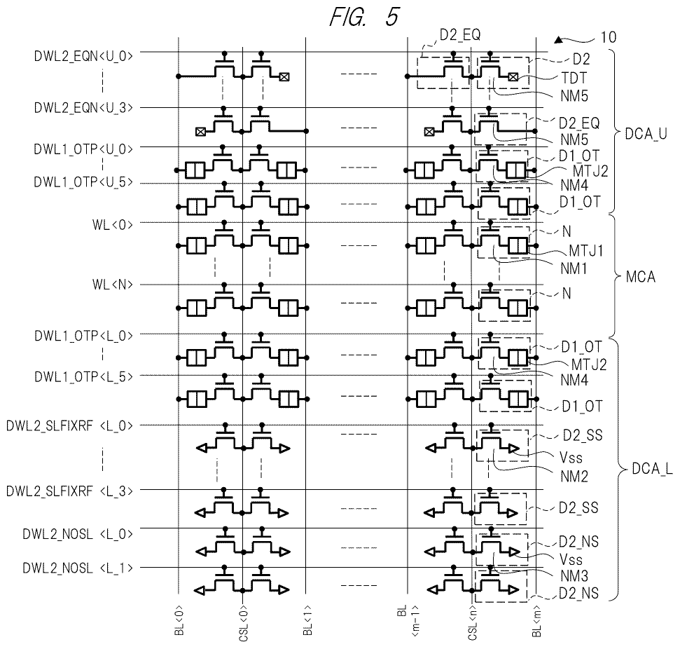

FIG. 5 is a circuit diagram showing the configuration of the memory array 10 according to the first embodiment. FIG. 5 illustrates only the memory cell region MCA shown by FIG. 1, the dummy cell region (second dummy cell region) DCA_U arranged between the memory cell region MCA and the first side 10_1A (see FIG. 1), and the dummy cell region (first dummy cell region) DCA_L arranged between the memory cell region MCA and the first side 10_1B (see FIG. 1).

In FIG. 5, the memory cell, the dummy cell, the bit line, and the source line shown in the memory cell region MCA and in the dummy cell regions DCA_U, DCA_L are schematically illustrated, but are illustrated in conformity with actually planar arrangement of the semiconductor substrate.

In the plan view, as shown in FIG. 1, the word lines (first word lines) WL<0> to WL<N> are arranged on the row of the memory cell region MCA, and the gate terminal of the transistor (first transistor) NM1, which configures the memory cell N arranged on the row arranging it, is connected to the word lines WL<0> to WL<N>. As shown in FIG. 5, the source terminal TST (FIG. 2A) of the transistor NM1 configuring the memory cell N is connected to the corresponding source line (for example, CSL<n>), and the drain terminal TDT (FIG. 2A) is connected to the corresponding bit line (for example, BL<m>) via the storage element (first storage element) MTJ1 and the terminal TMT (FIG. 2A).

On the row of the dummy cell region DCA_U, the word lines DWL2_EQN<U_0> to DWL2_EQN<U_3> and the word lines DWL1_OTP<U_0> to DWL1_OTP<U_5> are arranged. Here, the word lines DWL2_EQN<U_0> to DWL2_EQN<U_3> correspond to the word lines DWL2<U_0> to DWL2<U_n> shown by FIG. 1 and are arranged on the row arranging the dummy cell D2. In addition, the word lines DWL1_OTP<U_0> to DWL1_OTP<U_5> correspond to the word lines DWL1<U_0> to DWL2<U_n> shown in FIG. 1, and are arranged on the row arranging the dummy cell D1.

In addition, on the row of the dummy cell region DCA_L, the word lines DWL2_SLFIXRE<L_0> to DWL2_SLFIXRE<L_3>, the word lines DWL2_NOSL<L_0> to DWL2_NOSL<L_1>, and the word lines DWL1_OTP<L_0> to DWL1_OTP<L_5> are arranged. Here, the word lines DWL2_SLFIXRE<L_0> to DWL2_SLFIXRE<L_3> and the word lines DWL2_NOSL<L_0> to DWL2_NOSL<L_1> correspond to the word lines DWL2<L_0> to DWL2<L_n> shown in FIG. 1, and are arranged on the row arranging the dummy cell D2. Further, the word lines DWL1_OTP<L_0> to DWL1_OTP<L_5> correspond to the word lines DWL1<U_0> to DWL2<U_n> shown in FIG. 1, and arranged on the row arranging the dummy cell D1. The dummy cell region DCA_U will be explained later in a second embodiment, so that its description will be omitted here.

### <<Dummy Cell Region DCA_L>>

In the plan view in FIG. 5, a matrix having twelve rows is arranged in the dummy cell region DCA_L. The dummy cell D1 (D1_OT) is arranged on six rows adjacent to the memory cell region MCA among the twelve rows, and the dummy cell D2 (D2_SS, D2_NS) is arranged on the remaining six rows outside it. Of course, this row number is one example, and the present embodiment is not limited to its row number.

As shown in FIG. 5, on the row on which the dummy cells (first dummy cell) D2_SS, D2_NS are arranged, the word lines (second word line) DWL2_SLFIXRF<L_0> to DWL2_SLFIXRF<L_3> and the word lines (third word line) DWL2_NOSL<L_0> to DWL2_NOSL<L_1> are arranged, and the gate terminal of the transistor (second transistor) NM2 configuring the dummy cell D2_SS is connected to the word lines DWL2_SLFIXRF<L_0> to DWL2_SLFIXRF<L_3> arranged on the row arranging the dummy cell, and the gate terminal of the transistor NM3 configuring the dummy cell D2_NS is connected to the word lines DWL2_NOSL<L_0> to DWL2_NOSL<L_1> arranged the row arranging the dummy cell.

In addition, the source terminal of the transistor NM2 configuring the dummy cell D2_SS is connected to the source line (for example, CSL<n>) corresponding to the column arranging the dummy cell, and a predetermined voltage (for example, ground voltage Vss) is supplied to the drain terminal. Similarly, the source terminal of the transistor NM3 configuring the dummy cell D2_NS is connected to the source line (for example, CSL<n>) corresponding to the column arranging the dummy cell, and the predetermined voltage (for example, ground voltage Vss) is supplied to the drain terminal. The transistor configuring the dummy cell D2_SS and the transistor configuring the dummy cell D2_NS are denoted by the different reference numerals conveniently for explanation, but both sizes and characteristics are equal to each other.

In performing the reading operation of the date from the memory cell N, the control circuit 15 shown by FIG. 1 supplies, to the word lines DWL2_SLFIXRE<L_0> to DWL2_SLFIXRF<L_3>, such a selection signal as to make the transistor NM2 the conductive state, and supplies, to the word lines DWL2_NOSL<L_0> to DWL2_NOSL<L_1>, such a selection signal as to make the transistor NM3 the non-conductive state. Consequently, the predetermined voltage (ground voltage Vss) is supplied to the source lines CSL<0> to CSL<n> via the transistor N2 configuring the dummy cell D2_SS. When the source lines CSL<0> to CSL<n> have the predetermined voltage, the voltage of the bit lines BL<0> to BL<m> becomes a voltage corresponding to a state of the storage element MTJ1 by using the predetermined voltage as a reference voltage, is amplified by the sense amplifier 13 (FIG. 1), and is read out.

At a time of performing the reading operation, the predetermined voltage is supplied in parallel to each source line (for example, CSL<n>) by the plurality of transistors (in FIG. 5, eight transistors), so that securely fixing the voltage of the source line to the predetermined voltage becomes possible and a reduction of the reading of the fault data is possible.

In performing the reading operation, as the number of transistors connected between the source line and the predetermined voltage is larger, securely fixing the voltage of the source line to the predetermined voltage is possible, but a current flowing between the source line and the predetermined voltage increases. Therefore, in FIG. 5, such a selection as to make the transistor NM3 of the dummy cell D2_NS the non-conductive state is supplied from the control circuit 15 to the word lines DWL2_NOSL<L_0> to DWL2_NOSL<L_1> connected to the dummy cell D2_NS having the same configuration as that of the dummy cell D2_SS. Consequently, while the plurality of dummy cells D2 mutually having the same configuration are arranged regularly in the dummy cell region DCA_L, the reduction of the reading of the fault data is possible with suppressing an increase in power consumption.

In order to further obtain the reduction of the power consumption, the drain terminal of the transistor NM3 configuring the dummy cell D2_NS may be in the floating state so as not to supply the predetermined voltage, and the source terminal of the transistor NM3 may further be separated from the source line and be made in the floating state.

In shown by FIG. 5, on the row arranging the dummy cell (second dummy cell) D1_OT, the word lines (fourth word line) DWL1_OTP<L_0> to DWL1_OTP<L_5> are arranged, a gate terminal of transistor NM4 a (third transistor) configurating the dummy cell D1_OT is connected to the word lines DWL1_OTP<L_0> to DWL1_OTP<L_5> arranged on the row arranging the dummy cell, the source terminal of the transistor NM4 is connected to the source line (for example, CSL<n>) arranged on the column arranging the dummy cell, and the drain terminal is connected to the bit line (for example, BL<m>) arranged on the column arranging the dummy cell via a storage element (second storage element) MTJ2.

The dummy cell D1_OT is a memory cell for the OTP, and trimming information etc. are written previously in it. For example, by breaking the storage element MTJ2, data configurating the trimming information etc. is written it the dummy cell D1_OT. In order that the data is written depending on whether the storage element MTJ2 is broken, a difference between a resistance value at the time of not breaking the storage element MTJ2 and a resistance value after the breaking can be increased. In addition, since the dummy cell D1_OT has the configuration in which the data is read with complementarity, the difference between the resistance values can further be increased.

For example, at the time of writing and/or reading the complementary data in and/or from two dummy cells D1_OT connected to the source line CSL<n> and the word line DWL1_OT<L_5>, a voltage difference between the bit lines BL<m−1> and BL<m> is read, which makes it possible to read the complementary data. Thus, the difference between the resistance values is increased, which makes it possible to read the correct trimming information etc. from the dummy cell D1_OT even if the memory cell arranged outside the memory cell MCA has large variations of the resistance value at a time of manufacture.

In this way, according to the first embodiment, since the dummy cell D2_SS arranged in the dummy cell region is used for supplying the predetermined voltage to the source line at the time of the reading, effective usage of the dummy cell region is possible and the reduction of the reading of the fault data is also possible. In addition, the trimming information etc. can also be stored in the dummy cell region by using the dummy cell D1_OT, which makes it further possible to effectively use the dummy cell region.

In addition, the storage element MTJ is not used for supplying the predetermined voltage to the source line, so that the predetermined voltage can be supplied to the source line without affecting the variations of the storage element MTJ.

Connection between the source line and the predetermined voltage is made by the plurality of parallel connected transistors NM2, so that even if the variations of the characteristics of the transistor NM2 are present, it is possible to surely supply the predetermined voltage to the source line. In addition, since the dummy cell D2_SS is arranged at the outer circumferential portion in the memory array 10, On-resistance of the transistor NM2 is considered to be high. However, since the transistors NM2 parallel connected as shown by FIG. 5 are used, the connection between the predetermined voltage and the source line can be made by low resistance (composite resistance of the transistors NM2 parallel connected and made in the conductive state).

FIG. 5 shows an example in which the dummy cells DS SS arranged on four rows are used for supplying the predetermined voltage to the source line. However, the present embodiment is not limited to this, and the dummy cell D2_SS arranged on one row or the dummy cells D2_SS arranged on five or more rows may be used.

In addition, instead of or together with the dummy cell D2_SS, the dummy cell D1 (for example, D1_OT) having the storage element MTJ2 may be used as the dummy cell for supplying the predetermined voltage to the source line. In this case, it is preferable to previously perform a processing such as the writing to the storage element MTJ2 so that its resistance value becomes small.

The following configuration is also considered: the dummy cell D2_SS is not used, for example, the plurality of transistors connected between the predetermined voltage (ground voltage Vss) and the source lines CSL<0> to CSL<n> are provided outside the memory array 10. However, in a case of such a configuration, outside the memory array 10 a region for forming the transistor becomes necessary and a region for forming a wiring(s) connecting the transistor and the source line becomes necessary, which bring an increase of areas. In addition, depending on parasitic capacitance of the wiring connecting the transistor and the source line, an increase of the parasitic capacitance connected to the source line is considered, so that an interval of time until the source line is set to the predetermined voltage is considered to lengthen.

According to the first embodiment, since such a transistor and a wiring are unnecessary, it is possible to achieve the miniaturization and prevent the lengthening of the interval of time until the source line is set to the predetermined voltage.

### Second Embodiment

A memory array 10 according to a second embodiment will be explained by using FIG. 5.

In the plan view, the matrix having twelve rows is arranged on the dummy cell region DCA_U shown by FIG. 5. Among the twelve rows, the six rows adjacent to the memory cell region MCA arranges a dummy cell D1 (D1_OT), and the remaining six rows outside it arrange a dummy cell D2 (D2_EQ). Of course, this row number is one example, and the present embodiment is not limited to this row number.

As shown in FIG. 5, word lines (second word lines) DWL2_EQN<U_0> to DWL2_EQN<U_3> are arranged on the row arranging the dummy cell (first dummy cell) D2_EQ, and a gate terminal of a transistor (second transistor) NM5 configuring the dummy cell D2_EQ is connected to the word lines DWL2_EQN<U_0> to DWL2_EQN<U_3> arranged on the row arranging the dummy cell.

In addition, a source terminal of the transistor NM5 configurating the dummy cell D2_EQ is connected to the source line (for example, CSLM<n>) corresponding to the column arranging the dummy cell, and a drain terminal is connected to the bit line (for example, BL<m−1>) or BL<m>).

Note that in FIG. 5, the gate terminal is connected to the word line DWL2_EQN<U_0> or DWL2_EQN<U_3>, the source terminal is connected to the source line (CSL<n>), and the cell having the transistor NM5 whose drain terminal TDT is in the floating state indicates the dummy cell D2.

The dummy cell D2_EQ is used for equalizing the bit line and the source line before and the like performing the reading operation of the memory cell N. The voltage of the bit line (for example, BL<m>) is fixed to the predetermined voltage (for example, ground voltage Vss) before reading the data of the memory cell N, transitions from the predetermined voltage to a voltage determined by the resistance value of the storage element MTJ1 of the memory cell N when the reading operation begins, and then is amplified by the sense amplifier. That is, before performing the reading operation, the bit line and the source line requires being equalized.

In the second embodiment, the control circuit 15 shown by FIG. 1 supplies, to the word lines DWL2_EQNKU 0> to DWL2_EQN<U_3>, such an election signal to make the transistor NM5 in the conductive state before performing the reading operation to the memory cell N. More specifically, the control circuit 15 supplies the above selection signal to the word lines DWL2_EQN<U_0> to DWL2_EON<U_3> before performing the reading operation to the memory cell N, and then supplies, to the word lines DWL2_EQN<U_0> to DWL2_EQN<U_3>, such a selection signal as to make the transistor NM5 in the non-conductive state when the reading operation to the memory cell N begins. Consequently, the transistor NM5 becomes the conductive state in a part of interval of time in which the transistor NM2 in the dummy cell D2_SS becomes the conductive state, and then the transistor NM5 becomes the non-conductive state.

As a result, an equalizing operation for reducing a voltage difference between the bit line and the source line is performed by the transistor NM2 in the dummy cell D2_SS in the part of the interval of time in which the predetermined voltage is supplied to the source line. Before beginning the reading operation of the memory cell N, the above equalizing operation by the dummy cell D2_EQ ends, and the voltage of the bit line varies according to the data of the memory cell N.

As shown by FIG. 5, on the row arranging the dummy cell (third dummy cell) D1_OT, the word lines (fifth word line) DWL1_OTP<U_0> to DWL1_OTP<U_5> are arranged. The dummy cell D1_OT is the same as the dummy cell D1_OT explained in the dummy cell region DCA_L of the first embodiment, and is a memory cell for the OTP. The dummy cell D1_OT has already been described, so that its detailed description will be omitted.

An operation before performing the reading operation of the memory cell N has been explained as timing of performing the equalization, but the present embodiment is not limited to this. For example, in the reading operation, it is preferable that the bit line not to be selected by the column decoder 12 (FIG. 1) continues the equalization even in the interval of time of the reading operation. For example, when the bit line BL<m> shown in FIG. 5 is selected by the column decoder 12, the bit line BL<m−1> becomes not-selected. Even in the interval of time in which the reading operation is performed, the dummy cell D2_EQ connected to the bit line BL<m−1> connects the bit line BL<m−1> and the source line CSL<n> and continues the equalization. In order to realize this, for example, the column address signal (C address: FIG. 1) has only to be supplied to the control circuit 15, and the control circuit 15 has only to supply the selection signal to the word line (in an example of FIG. 5, DWL2_EQN<U_0>) of the dummy cell D2_EQ connected to the bit line BL<m−1> based on the column address signal even in the interval of time of the reading operation of the memory cell N.

In order to supply the predetermined voltage to the bit lines BL<0> to BL<m> by the equalization, the predetermined voltage requires to be supplied to the source lines CSL<0> to CSL<n>. As explained in the first embodiment, the predetermined voltage (ground voltage Vss) is supplied to the source line CSL by the dummy cell (second dummy cell) D2_SS.

However, the following configuration may be used: the dummy cell DS SS is not used, for example, the plurality transistors connected between the predetermined voltage (ground voltage Vss) and the source lines CSL<0> to CSL<n> are provided outside the memory cell 10. However, in such a configuration, the region for forming the transistor outside the memory array 10 is required, and the region for forming the wiring connecting the transistor and the source line becomes necessary, which bring the increase of areas. In addition, depending on the parasitic capacitance of the wiring connecting the transistor and the source line, the increase of the parasitic capacitance of the wiring connecting the bit line and the source line is considered, and the reading operation is considered to be late.

According to the second embodiment, since the supply of the predetermined voltage to the source line and the equalization thereof are performed by the dummy cells D2_SS, D2_EQ, it is possible to achieve the miniaturization and to achieve speeding-up of the reading operation.

According to the second embodiment, the dummy cell D2_EQ in the dummy cell region is used for equalizing the bit line, so that the effective use of the dummy cell region is possible.

Note that as shown in FIG. 5, the dummy cell D2_EQ is arranged at the outer circumferential portion in the memory array the characteristics of the 10. Consequently, transistor NM5 configurating the dummy cell D2_EQ is bad, for example, an increase of threshold voltages is considered. However, the transistor NM5 is a transistor used for equalizing the bit line and the source line, so that the increase in the threshold voltages brings no problem.

FIG. 5 shows an example in which the dummy cell having no storage element MTJ2 is used for the equalization, but the equalization may be performed by the dummy cell D1 (for example, D1_OT) having the storage element MTJ2. In this case, during the equalization, the source line and the bit line are connected via the transistor NM4 and the storage element MTJ2. That is, the connection of the source line and the bit line is made by comparatively high resistance.

FIG. 5 shows an example of: performing the equalization by the dummy cell D2_EQ arranged in the dummy cell region DCA_U; and supplying the predetermined voltage to the source line by the dummy cell D2_SS arranged on the dummy cell region DCA_L, but the present embodiment is not limited to this. For example, the dummy cell D2_EQ for performing the equalization and the dummy cell D2_SS for supplying the predetermined voltage may be arranged on each of the dummy cell regions DCA_U, DCA_L.

As described above, the invention made by the present inventors have been specifically explained based on the embodiments, but the present invention is not limited to the above embodiments and, needless to say, can variously be modified within a range of not departing from the gist thereof.

What is claimed is:

1. A semiconductor device comprising:
a pair of first sides extending in a first direction and a pair of second sides extending in a second direction interposing with the first sides; and
a memory array having a plurality of rows parallel to the first sides and a plurality of columns parallel to the second sides,
wherein in a plan view, the memory array has a memory cell region arranged between the pair of first sides and a dummy cell region arranged between the memory cell region and the first sides,
wherein in the memory array, a first word line and a plurality of transistors having a first transistor whose gate terminal is connected to the first word line and having a first storage element are arranged on each row arranged in the memory and a second word line and a plurality of first dummy cell having a second transistor whose gate terminal is connected to the second word line and to whose drain terminal a predetermined voltage is supplied are arranged on each row arranged in the dummy cell region,
wherein in the memory array, a source line and a bit line are arranged on each column, a source terminal of the first transistor of the memory cell is connected to the source line arranged on each column arranged in the memory cell region and a drain terminal of the drain transistor of the memory cell is connected to the bit line arranged via the first storage element on each column arranged in the memory cell region, and a source terminal of the second transistor of the first dummy cell is connected to the source line arranged on each column arranged in the dummy cell region,
wherein the plurality of memory cells are arranged at a first pitch in the first direction and at a second pitch in the second direction in the memory region, and the plurality of first dummy cells are arranged at the first pitch in the first direction and at the second pitch in the second direction in the dummy cell region, and
wherein the semiconductor device includes:
a row decoder connected to the plurality of first word lines, and selecting a first word line according to a row address signal at a time of a reading operation; and
a control circuit connected to the second word line, and supplying a selection signal for making the second transistor of the first dummy cell in a conductive state so that the predetermined voltage is supplied to the source line at the time of the reading operation.

2. The semiconductor device according to claim 1,
wherein the dummy cell region further has a row on which the plurality of first dummy cells connected to a third word line different from the second word line are arranged, and
wherein the third word line is connected to the control circuit, and the control circuit makes the second transistor of the plurality of first dummy cells, which are connected to the third word lines, in a non-conductive state at the time of the reading operation.

3. The semiconductor device according to claim 1,
wherein the source line is shared between the columns adjacent to each other.

4. The semiconductor device according to claim 2,
wherein the dummy cell region has a row on which a plurality of second dummy cells connecting a fourth word line different from the second word line and the third word line are arranged,
wherein the second dummy cell has a third transistor and a second storage element connected to a drain terminal of the third transistor, a gate terminal of the third transistor is connected to the fourth word line, a source terminal thereof is connected to the source line, and a drain terminal thereof is connected to the bit line via the second storage element, and
wherein data of the second storage element is previously set, and the control circuit makes the thirds transistor in a conductive state by the fourth word line at a time of reading the data of the second storage element.

5. The semiconductor device according to claim 4,
wherein the first storage element and the second storage element are each an element having a three-layer structure obtained by layering a pinned layer of a magnetic tunneling junction, a tunneling layer, and a free layer.

6. The semiconductor device according to claim 5,
wherein the semiconductor device has a column decoder connected to the plurality of bit lines in the memory cell region and selecting the bit line according to a column address signal, and
wherein the row decoder, the column decoder, and the control circuit are arranged outside the memory array.

7. A semiconductor device comprising:
a pair of first sides extending in a first direction and a pair of second sides extending in a second direction intersecting with the first sides; and
a memory array having a plurality of rows parallel to the first sides and a plurality of columns parallel to the second sides,
wherein in a plan view, the memory array has a memory cell region arranged between the pair of first sides and a dummy cell region arranged between the memory cell region and the first sides,
wherein in the memory array, a first word line and a plurality of memory cells having a first transistor whose gate terminal is connected to the first word line and a first storage element are arranged on each row arranged in the memory cell region, and a second word line and a plurality of first dummy cell having a second transistor whose gate terminal is connected to the second word line are arranged on each row arranged in the dummy cell region,
wherein in the memory array, a source line and a bit line are arranged on each column, a source terminal of the first transistor of the memory cell is connected to the source line arranged on each column arranged in the memory cell region and a drain terminal of the first transistor of the memory cell is connected to a bit line arranged via the first storage element on each column arranged in the memory cell region, and a source terminal of the second transistor of the first dummy cell is connected to the source line arranged on each column arranged in the dummy cell region and a drain terminal of the second transistor of the first dummy cell is connected to the bit line arranged on each column arranged in the dummy cell region,
wherein the plurality of memory cells are arranged at a first pitch in the first direction and at a second pitch in the second direction in the memory cell region, and the plurality of first dummy cells are arranged at the first pitch in the first direction and at the second pitch in the second direction in the dummy cell region, and
wherein the semiconductor device includes:
a row decoder connected to the first word line and selecting the first word line according to a row address signal at a time of a reading operation; and
a control circuit connected to the second word line and supplying a selection signal for making the second transistor in a conductive state to reduce a voltage difference between the source line and the bit line.

8. The semiconductor device according to claim 7,
wherein the source line shared between the columns adjacent to each other.

9. The semiconductor device according to claim 8,
wherein the dummy cell region further has a row on which a plurality of second dummy cells connected to a third word line different from the second word line are arranged,
wherein the second dummy cell has a third transistor whose gate terminal is connected to the third word line, whose source terminal is connected to the source line, and to whose drain terminal a predetermined voltage is supplied, and
wherein the third word line is connected to the control circuit, the control circuit supplies, to the third word line, a selection signal for making the third transistor in a conductive state so that the predetermined voltage is supplied to the source line at the time of the reading 15 operation.

10. The semiconductor device according to claim 9,
wherein the dummy cell region further has a column of a plurality of second dummy cell connected to a fourth word line different from the second word line and the third word line, and
wherein the fourth word line is connected to the control circuit, the control circuit makes, in a non-conductive state, the third transistor of the second dummy cell connected to the fourth word line at the time of the reading operation.

11. The semiconductor device according to claim 10,
wherein the dummy cell region has a row on which a plurality of third dummy cells connecting a fifth word line different from the second word line, the third word line, and the fourth word line are arranged,
wherein the third dummy cell has a fourth transistor and a second storage element connected to a drain terminal of the fourth transistor, a gate terminal of the fourth transistor is connected to the fifth word line, a source terminal thereof is connected to the source line, and a drain terminal thereof is connected to the bit line via the second storage element, and
wherein data of the second storage element is previously set, and the control circuit makes the fourth transistor in the conductive state by the fifth word line at a time of reading the data of the second storage element.

12. The semiconductor device according to claim 11,
wherein the first storage element and the second storage element are each an element having a three-layer structure obtained by layering a pinned layer of magnetic tunneling junction, a tunneling layer, and a free layer.

13. The semiconductor device according to claim 12,
wherein the semiconductor device has a column decoder connected to the plurality of bit lines in the memory cell region and selecting a bit line according to a column address signal, and
wherein the row decoder, the column decoder, and the control circuit are arranged outside the memory array.

14. The semiconductor device according to claim 13,
wherein a row arranging the plurality of second dummy cell connected to the third word line is arranged in the first dummy cell region between one first side out of the pair of first sides and the memory cell region,
wherein a row arranging the plurality of first dummy cells connected to the second word line and a row arranging the plurality of first dummy cells connected to a fourth word lines are arranged in the second dummy cell region between the other first side out of the pair of first sides and the memory cell region, and
wherein a row arranging the plurality of third dummy cells connected to a fourth word line is arranged in the first dummy cell region and the second dummy cell region.
